(19) United States
(12) Patent Application Publication
(10) Pub. No.: US 2022/0036780 A1
(43) Pub. Date: Feb. 3, 2022

(54) ELECTRICAL CONDUCTIVITY TEST STRUCTURE, THIN FILM TRANSISTOR ARRAY SUBSTRATE, AND DISPLAY PANEL

(71) Applicant: Century Technology (Shenzhen) Corporation Limited, Shenzhen (CN)

(72) Inventors: QI XU, Shenzhen (CN); RUI LI, Shenzhen (CN); YUAN XIONG, Shenzhen (CN); HUI WANG, Shenzhen (CN); WEN-LIN CHEN, Shenzhen (CN); CHIH-CHUNG LIU, New Taipei (TW)

(21) Appl. No.: 17/206,747

(22) Filed: Mar. 19, 2021

(30) Foreign Application Priority Data
Jul. 31, 2020 (CN) 202010756336.6

(51) Int. Cl. G09G 3/00; G01N 27/04; G09G 3/36; G02F 1/13

(52) U.S. Cl. CPC G09G 3/006; G02F 1/1309; G09G 3/3648; G01N 27/04

(57) ABSTRACT

An electrical conductivity test structure for testing an electrical conductivity of target traces in a display panel includes a controller, a first conductive layer, and a second conductive layer. The first conductive layer includes first and second traces. The at least one first trace and the at least one second trace are connected in parallel. Each first trace connects with the target trace and with the controller and each second trace connects with the target trace and with the controller. The second conductive layer connects with the first trace but is electrically insulated from the second trace. The second conductive layer transmits test signals to the first trace to test electrical conductivity between the controller and the target trace.

### FIELD

The subject matter herein generally relates to a field of display, and particularly to an electrical conductivity test structure, a thin film transistor array substrate including the electrical conductivity test structure and a display panel including the thin film transistor array substrate.

### BACKGROUND

A liquid crystal display (LCD) panel includes a thin film transistor array substrate and a color filter substrate opposite to each other. A test pad is used to test conductivity of traces (such as gate line, data line, or trace in a non-display area) in the thin film transistor array substrate and the color filter substrate after the thin film transistor array substrate and the color filter substrate are assembled.

Traditional test methods use a probe to electrically contact the test pad, and to input a test signal through the probe to test whether the traces in the array substrate and the color filter substrate are conductive. However, the test pad can be scratched since the probe is rigid and sharp, causing deterioration of electrical signal during operation of the LCD panel.

Therefore, there is room for improvement in the art.

### BRIEF DESCRIPTION OF THE DRAWINGS

Implementations of the present disclosure will now be described, by way of embodiment, with reference to the attached figures.

FIG. 1 is a cross-sectional view of a display device including a thin film transistor array substrate according to an embodiment of the disclosure.

FIG. 2 is a planar view of the thin film transistor array substrate including an electrical conductivity test structure in the display device shown in FIG. 1.

FIG. 3A is a planar view of the electrical conductivity test structure shown in FIG2.

FIG. 3B is a cross-sectional view along line D-D of FIG. 3A.

FIG. 4A is a planar view of the electrical conductivity test structure used in a manufacturing process.

FIG. 4B is a cross-sectional view along line A-A of FIG. 4A.

FIG. 5A is another planar view of the electrical conductivity test structure used in the manufacturing process.

FIG. 5B is a cross-sectional view along line B-B of FIG. 5A.

FIG. 6A is another planar view of the electrical conductivity test structure used in the manufacturing process.

FIG. 6B is a cross-sectional view along line C-C of FIG. 6A.

### DETAILED DESCRIPTION

It will be appreciated that for simplicity and clarity of illustration, where appropriate, reference numerals have been repeated among different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “coupled” is defined as connected, whether directly or indirectly through intervening components, and is not necessarily limited to physical connections. The connection can be such that the objects are permanently connected or releasably connected. The term “comprising” when utilized, means “including, but not necessarily limited to”; it specifically indicates open-ended inclusion or membership in the so-described combination, group, series, and the like.

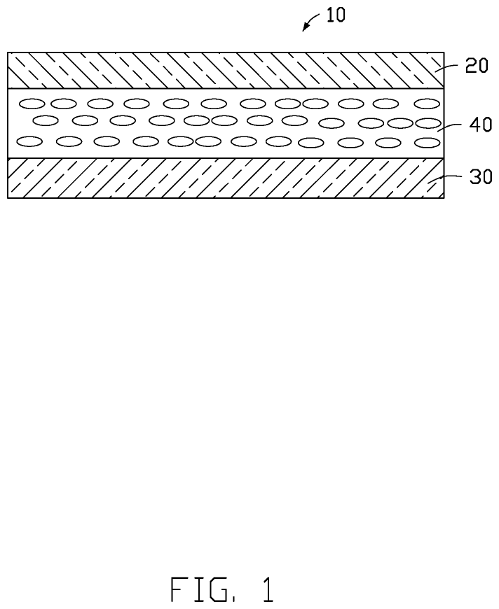

FIG. 1 shows a display panel 10 including a color filter substrate 20, a thin film transistor array substrate 30 opposite to the color filter substrate 20, and a liquid crystal layer 40 between the color filter substrate 20 and the thin film transistor array substrate 30. The liquid crystal layer 40 includes liquid crystal molecules densely arranged. The liquid crystal molecules rotate to follow a voltage difference between the color filter substrate 20 and the thin film transistor array substrate 30, the rotation angle of the liquid crystal molecules varying with the voltage difference. The display panel 10 can be controlled to display different images by controlling the voltage difference. A surface of the display panel 10 displaying the images is a surface of the color filter substrate 20 away from the thin film transistor array substrate 30. The display panel 10 also includes other necessary elements, only elements related to the present disclosure in the display panel 10 are described below.

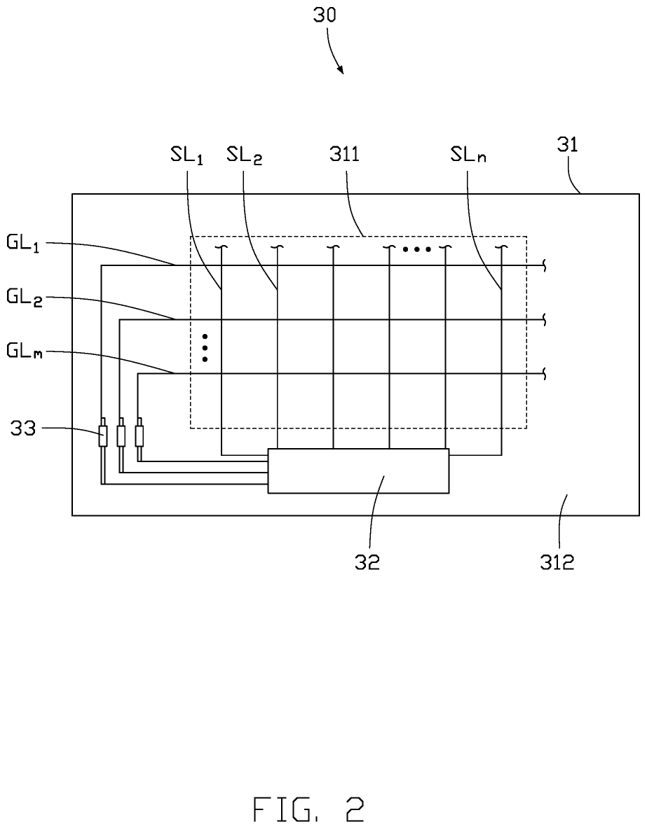

As shown in FIG. 1 and FIG. 2, the thin film transistor array substrate 30 includes a glass substrate 31 defining a display area 311 and a non-display area 312 connected with the display area 311. The non-display area 312 surrounds the edge of the display area 311. The display area 311 is configured to display the images during operation of the display panel 10. Elements made of opaque materials (such as metal, plastic, etc.) are in the non-display area 312. A border covers the non-display area 312 to improve aesthetics of the display panel 10.

As shown in FIG. 2, a plurality of gate lines GL₁-GLₘ and a plurality of data lines SL₁-SLₙ are in the display area 311 of the glass substrate 31. The gate lines GL₁-GLₘ are in parallel with each other, and the data lines SL₁-SLₙ are in parallel with each other. An extension direction of the gate lines GL₁-GLₘ is perpendicular to an extension direction of the data lines SL₁-SLₙ.

Either or both of the gate lines GL₁-GLₘ and the data lines SL₁-SLₙ can be defined as target traces in the present disclosure. In another embodiment of the disclosure, target traces can also include other conductive traces in the display panel 10 except for the lines GL₁-GLₘ and the data lines SL₁-SLₙ.

As shown in FIG. 2, a controller 32 and an electrical conductivity test structure 33 are in the non-display area 312 of the glass substrate 31. The electrical conductivity test structure 33 is electrically connected with the controller 32 and the target traces. The gate lines GL₁-GLₘ and the data lines SL₁-SLₙ are electrically connected to the controller 32. The controller 32 is configured to output scan signals to the gate lines GL₁-GLₘ and to output image data to the data lines SL₁-SLₙ.

In this embodiment, the electrical conductivity test structure 33 is electrically connected with the controller 32 and the gate lines GL₁-GLₘ. The electrical conductivity test structure 33 is electrically connected with the controller 32 and the data lines SL₁-SLₙ when the data lines SL₁-SLₙ are defined as the target traces.

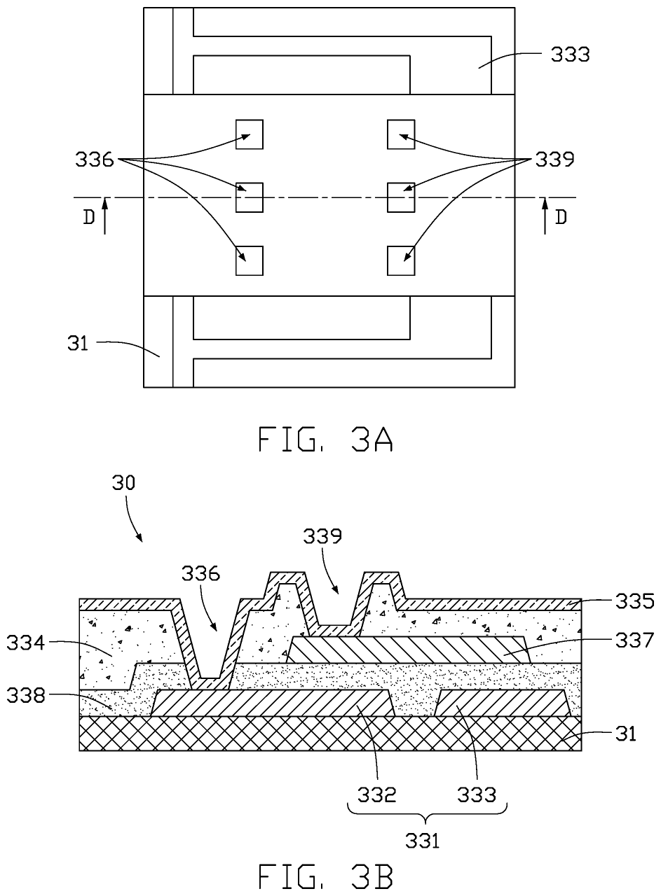

As shown in FIG. 3A and FIG. 3B, the electrical conductivity test structure 33 includes a first conductive layer 331including a first trace 332 and a second trace 333. The first trace 332 and the second trace 333 are connected in parallel. One end of the first trace 332 is electrically connected with the target traces, and the other end is electrically connected with the controller 32. One end of the second trace 333 is electrically connected with the target traces, and the other end is electrically connected with the controller 32. In other embodiments of the present disclosure, the first conductive layer 331 may include a plurality of first traces 332 and a plurality of second traces 333. The first conductive layer 331 may also include a plurality of first traces 332 and one second trace 333, or may include one trace 332 and a plurality of second traces 333.

As shown in FIG. 3A and FIG. 3B, the electrical conductivity test structure 33 further includes a first insulating layer 334 and a second conductive layer 335. The first insulating layer 334 partially covers the first conductive layer 331. The second conductive layer 335 is on a surface of the first insulating layer 334 away from the first conductive layer 331. That is, the first insulating layer 334 is between the first conductive layer 331 and the second conductive layer 335.

As shown in FIG. 3A and FIG. 3B, the electrical conductivity test structure 33 further includes a third conductive layer 337 and a second insulating layer 338. The third conductive layer 337 is between the first conductive layer 331 and the second conductive layer 335. The second insulating layer 338 is between the first conductive layer 331 and the third conductive layer 337.

The second insulating layer 338 covers and insulates the second trace 333 so that the second trace 333 is electrically insulated from the third conductive layer 337. The first insulating layer 334 partially covers the third conductive layer 337. A portion of the first insulating layer 334 not covering the third conductive layer 337 is in contact with the second insulating layer 338.

A portion of the first insulating layer 334 and a portion of the second insulating layer 338 covering the first trace 332 define a plurality of first through holes 336. Each first through hole 336 penetrates through the first insulating layer 334 and the second insulating layer 338 to render the first trace 332 exposed. The second conductive layer 335 is in electrical contact with an exposed portion of the first trace 332.

The first insulating layer 334 is also provided with a plurality of second through holes 339. Each second through hole 339 penetrates the first insulating layer 334 and exposes the third conductive layer 337. The second conductive layer 335 and the third conductive layer 337 are in electrical contact through an exposed part of the first insulating layer 334, to electrically connect the first conductive layer 331 and the third conductive layer 337.

In this embodiment, the first conductive layer 331 (that is, the first trace 332 and the second trace 333) and the third conductive layer 337 are made of metal, while the second conductive layer 335 is made of indium tin oxide (ITO). In other embodiments, the first conductive layer 331, the second conductive layer 335, and the third conductive layer 337 may be made of other conductive materials.

The following describes a manufacturing method of the electrical conductivity test structure 33.

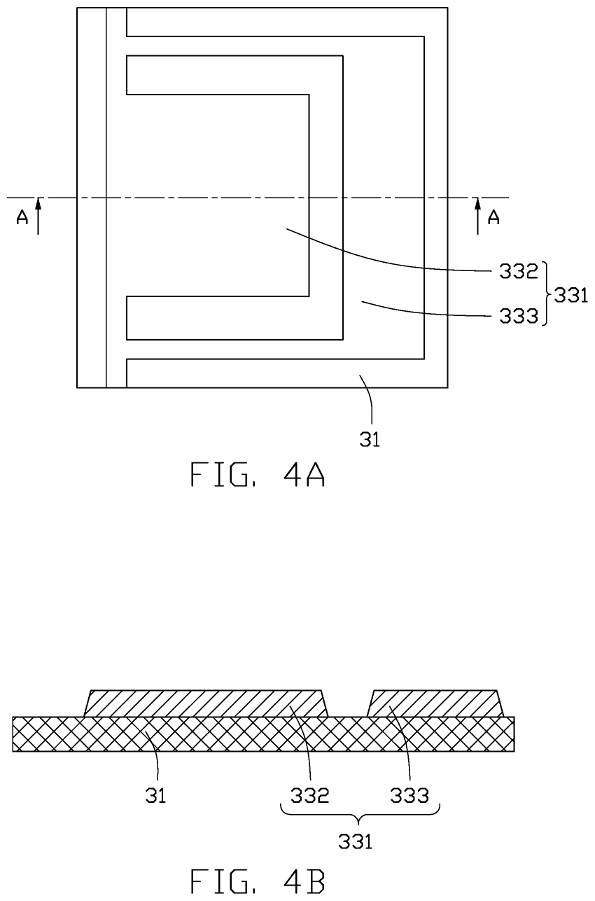

As shown in FIG. 4A and FIG. 4B, the first conductive layer 331 is formed on a surface of the glass substrate 31 by forming a complete metal layer and etching the complete metal layer, thereby the first trace 332 and the second trace 333 are formed.

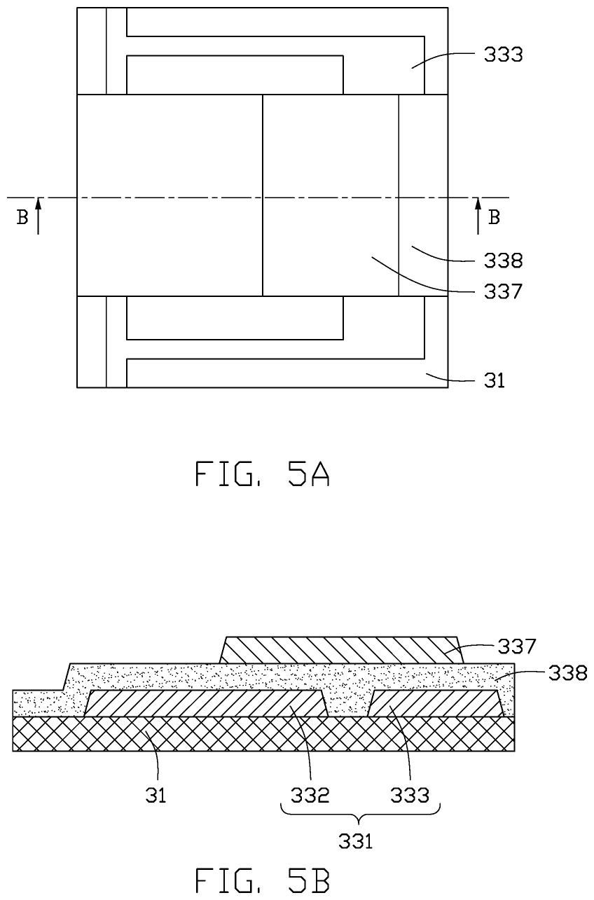

As shown in FIG. 5A and FIG. 5b, the second insulating layer 338 is formed on a surface of the first conductive layer 331 away from the glass substrate 31. The second insulating layer 338 at least partially covers the first trace 332 and the second trace 333. A third conductive layer 337 is formed on a surface of the second insulating layer 338 away from the glass substrate 31.

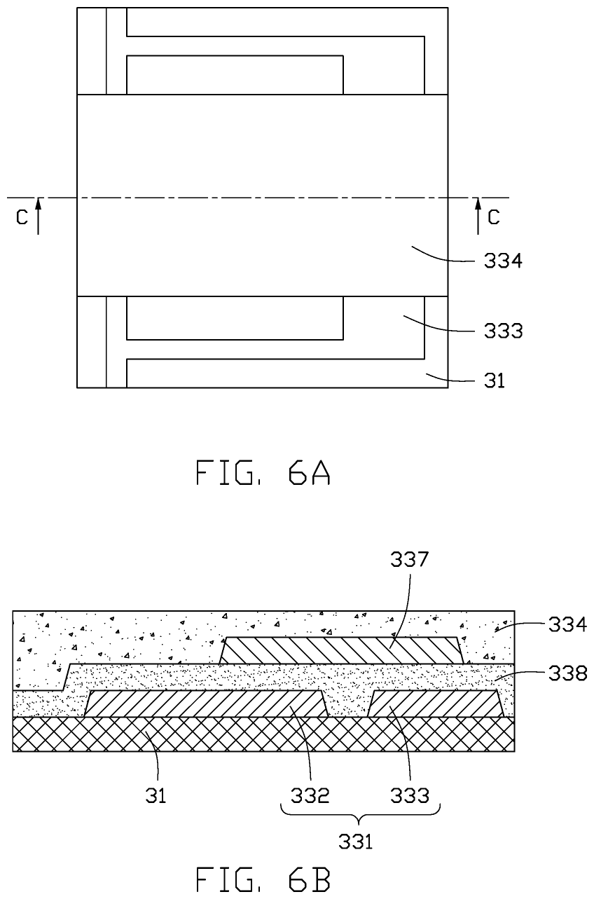

As shown in FIG. 6a and FIG. 6B, the first insulating layer 334 is formed on a surface of the third conductive layer 337 away from the glass substrate 31. The first insulating layer 334 completely covers the third conductive layer 337 and the second insulating layer 338.

The plurality of first through holes 336 penetrating both the first insulating layer 334 and the second insulating layer 338 is formed, and the plurality of second through holes 339 penetrating the first insulating layer 334 is formed. The first trace 332 is partially exposed through each first through hole 336. The third conductive layer 337 is partially exposed through each second through hole 339.

The second conductive layer 335 is formed on a surface of the first insulating layer 334 away from the glass substrate 31. The second conductive layer 335 is electrically connected with the first trace 332 by extending into each first through hole 336, also being electrically connected with the third conductive layer 337 by extending into each second through hole 339. The electrical conductivity test structure 33 after forming the second conductive layer 335 is as shown in FIG. 3a and FIG. 3B.

As shown in FIG. 3a and FIG. 3B, the electrical conductivity test structure 33 tests target traces for electrical conductivity. In this embodiment, the target traces in the display panel 10 when the color filter substrate 20 and the thin film transistor array substrate 30 are assembled are tested, and to check whether the target traces can transmit signals. A probe outside the display panel 10 makes contact with a surface of the second conductive layer 335 away from the first conductive layer 331 to electrically connect the probe and the second conductive layer 335. A test signal can be sent to the second conductive layer 335 through the probe. The test signal can be sent in turn to components in the display area 311 of the display panel 10 through the second conductive layer 335, the first conductive layer 331 (including the first trace 332 and the second trace 333), and the target traces, and the display panel 10 will be illuminated if the target traces in the display panel 10 are working normally. Abnormal working is indicated if the display panel 10 is not illuminated, wherein the target traces are failed.

The second conductive layer 335 can be scratched when contacted by the probe (in order to accurately transmit the test signal, the probe usually contacts a portion where the second conductive layer 335 extends into the first through hole 336) since the second conductive layer 335 is thin, and the first trace 332 under the second conductive layer 335 can also be scratched if the probe is not operated properly. The first trace 332 is in direct electrical contact with the controller 32 and the target traces in the display area 311, and electrical conductivity of the first trace 332 will be affected if the first trace 332 is scratched; an electrical signal sent from the controller 32 may fail to reach the target traces in the display area 311 through the first trace 332.

The electrical conductivity test structure 33 provided by this embodiment resolves the above problem by the second trace 333 being connected in parallel with the first trace 332.

If the first trace 332 is scratched by the probe and fails to transmit the electrical signal, the electrical signal output by the controller 32 can be transmitted to the target traces in the display area 311 through the second trace 333. The probe does not touch the second trace 333 because the second trace 333 is covered by the first insulating layer 334, the second insulating layer 338, and the third conductive layer 337. These provide effective protection to the second trace 333, and prevent it being scratched by the probe.

In addition, the electrical conductivity test structure 33 provided by this embodiment also resolves the above problems in relation to the third conductive layer 337.

The probe can contact a portion of the second conductive layer 335 extending in the second through hole 339 to avoid scratching the first trace 332, the probe is not able to scratch both the second conductive layer 335 and the third conductive layer 337. Even if the second conductive layer 335 is scratched, the test signal from the probe can be transmitted to the first trace 332 through the third conductive layer 337 since the third conductive layer 337 is electrically connected with the first trace 332 through the second conductive layer 335. The first trace 332 cannot be scratched because the probe contacts the portion of the second conductive layer 335 extending into the second through hole 339. The first trace 332 is free to normally transmit the electrical signal output by the controller 32 to the target traces in the display area 311 after the test.

In another embodiment of the present disclosure, the electrical conductivity test structure 33 may omit the first insulating layer 334 and the third conductive layer 337, wherein the second conductive layer 335 is on a surface of the second insulating layer 338 away from the glass substrate 31, and the second conductive layer 335 is in direct contact with the second insulating layer 338. The second conductive layer 335 is in electrical contact with an exposed part of the first trace 332 by extending into each first through hole 336. The electrical conductivity test structure 33 is very thin and the manufacturing process of the electrical conductivity test structure 33 is simple.

The electrical conductivity test structure 33 provided in the present embodiment resolves self-caused problems in testing arising from deterioration of the structure used for testing.

It is to be understood, even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present embodiments to the full extent indicated by the plain meaning of the terms in which the appended claims are expressed.

What is claimed is:

1. An electrical conductivity test structure configured for testing an electrical conductivity of a target trace in a display panel comprising a controller, the electrical conductivity test structure comprising:
a first conductive layer comprising at least one first trace and at least one second trace, the at least one first trace and the at least one second trace being connected in parallel, each of the at least one first trace being electrically connected to the target trace and the controller, and each of the at least one second trace being electrically connected with the target trace and the controller; and
a second conductive layer electrically connected with the at least one first trace and electrically insulated from the at least one second trace, the second conductive layer being configured to transmit test signals to the at least one first trace;
wherein the test signals are configured to test an electrical conductivity between the controller and the target trace.

2. The electrical conductivity test structure of claim 1, further comprising:
a first insulating layer between the first conductive layer and the second conductor layer, the first insulating layer electrically insulating the at least one second trace and the second conductive layer,
wherein the first insulating layer defines a plurality of first through holes, and the second conductive layer is electrically connected with the at least one first trace by the second conductive layer extending to the plurality of first through holes.

3. The electrical conductivity test structure of claim 2, further comprising:
a third conductive layer between the second conductive layer and the first conductive layer and electrically connected with the first conductive layer through the second conductive layer.

4. The electrical conductivity test structure of claim 3, further comprising:
a second insulating layer between the first conductive layer and the third conductive layer, the second insulating layer being configured for electrically insulating the at least one second trace and the third conductive layer,
wherein the second insulating layer defines a plurality of second through holes, and the second conductive layer is electrically connected with the third conductive layer by the second conductive layer extending to the plurality of second through holes.

5. The electrical conductivity test structure of claim 1, wherein the first conductive layer is made of metal, and the second conductive layer is made of indium tin oxide.

6. A thin film transistor array substrate, comprising:
a glass substrate defining a display area and a non-display area connected with the display area, the target trace being in the display area, and the controller being in the non-display area; and
an electrical conductivity test structure, comprising:
a first conductive layer comprising at least one first trace and at least one second trace, the at least one first trace and the at least one second trace are connected in parallel, each of the at least one first trace electrically connected to the target trace and the controller, and each of the at least one second trace electrically connected with the target trace and the controller; and
a second conductive layer electrically connected with the at least one first trace and electrically insulated from the at least one second trace, the second conductive layer configured to transmit test signals to the at least one first trace;
wherein the test signals are configured to test an electrical conductivity between the controller and the target trace.

7. The thin film transistor array substrate of claim 6, wherein the electrical conductivity test structure further comprises:
a first insulating layer between the first conductive layer and the second conductor layer for electrically insulating the at least one second trace and the second conductive layer;
wherein the first insulating layer defines a plurality of first through holes, and the second conductive layer is electrically connected with the at least one first trace by the second conductive layer extending to the plurality of first through holes.

8. The thin film transistor array substrate of claim 7, wherein the electrical conductivity test structure further comprises:
a third conductive layer between the second conductive layer and the first conductive layer and electrically connected with the first conductive layer through the second conductive layer.

9. The thin film transistor array substrate of claim 8, wherein the electrical conductivity test structure further comprises:
a second insulating layer between the first conductive layer and the third conductive layer for electrically insulating the at least one second trace and the third conductive layer;
wherein the second insulating layer defines a plurality of second through holes, and the second conductive layer is electrically connected with the third conductive layer by the second conductive layer extending to the plurality of second through holes.

10. The thin film transistor array substrate of claim 6, wherein the first conductive layer is made of metal, and the second conductive layer is made of indium tin oxide.

11. The thin film transistor array substrate of claim 6, wherein the electrical conductivity test structure is in the non-display area.

12. The thin film transistor array substrate of claim 7, wherein the electrical conductivity test structure is in the non-display area.

13. The thin film transistor array substrate of claim 6, wherein the target trace is a gate line; or
the target trace is a data line; or
the target trace comprises the gate line and the data line.

14. The thin film transistor array substrate of claim 7, wherein the target trace is a gate line; or
the target trace is a data line; or
the target trace comprises the gate line and the data line.

15. A display panel, comprising:
a color filter substrate;
a thin film transistor array substrate comprising:
a glass substrate defined a display area and a non-display area connected with the display area, the target trace being in the display area, and the controller being in the non-display area; and
an electrical conductivity test structure, comprising:
a first conductive layer comprising at least one first trace and at least one second trace, the at least one first trace and the at least one second trace are connected in parallel, each of the at least one first trace electrically connected to the target trace and the controller, and each of the at least one second trace electrically connected with the target trace and the controller; and
a second conductive layer electrically connected with the at least one first trace and electrically insulated from the at least one second trace, the second conductive layer configured to transmit test signals to the at least one first trace;
wherein the test signals are configured to test an electrical conductivity between the controller and the target trace; and
a liquid crystal layer between the color filter substrate and the thin film transistor array substrate, the color filter substrate, the liquid crystal layer, and the thin film transistor array substrate configured to display images in cooperation.

16. The display panel of claim 13, wherein the electrical conductivity test structure is in the non-display area.

17. The display panel of claim 13, wherein the target trace is a gate line; or
the target trace is a data line; or
the target trace comprises the gate line and the data line.

18. The display panel of claim 13, wherein the controller is configured to output a display signal to the target trace through the at least one first trace when the display panel displays images; or
the controller is configured to output a display signal to the target trace through the at least one second trace when the display panel displays images; or
the controller is configured to output a display signal to the target trace through the at least one first trace and the at least one second trace when the display panel displays images.
